(19) United States
(12) Patent Application Publication
(10) Pub. No.: US 2011/0277819 A1
(43) Pub. Date: Nov. 17, 2011

(54) BIFACIAL THIN FILM SOLAR PANEL AND METHODS FOR PRODUCING THE SAME

(75) Inventor: Ivan I. Scheulov, San Francisco, CA (US)

(73) Assignee: BAKERSUN, San Francisco, CA (US)

(21) Appl. No.: 13/104,763

(22) Filed: May 10, 2011

Related U.S. Application Data
(60) Provisional application No. 61/333,257, filed on May 11, 2010.
(60) Provisional application No. 61/333,258, filed on May 11, 2010.
(60) Provisional application No. 61/333,259, filed on May 11, 2010.

(51) Int. Cl. H01L 31/052; H01L 31/18

(52) U.S. Cl. 136/246; 29/890.033

(57) ABSTRACT

Bifacial solar cell panels and associated systems are provided. The panels include a plurality of semiconductor cells connected in series. A reflector is used to reflect light towards the backside of the panel. A long axis of the reflector is arranged to be parallel to the current flow of the panel.

### CROSS-REFERENCE TO RELATED APPLICATIONS

This patent application claims priority under 35 U.S.C. §119(e) to U.S. Provisional Patent Application No. 61/333,257, filed May 11, 2010, entitled “Bifacial Thin Film Silicon Solar Panel”, and to U.S. Provisional Patent Application No. 61/333,258, filed May 11, 2010, entitled “Bifacial CdTe Solar Panel”, and to U.S. Provisional Patent Application No. 61/333,259, filed May 11, 2010, entitled “Bifacial CIGS Solar Panel”. This patent application is also related to International Patent Application No. PCT/US2011/035929, filed on May 10, 2011. Each of the above-identified patent applications is incorporated herein by reference in its entirety.

### BACKGROUND

Photovoltaic panels can be made to convert sunlight into electricity. There are various technologies for making photovoltaic panels, including silicon wafer based, thin film silicon based, Copper-Indium-Gallium-Selenide (CIGS) thin film based and Cadmium-Telluride (CdTe) thin film based. Many commercially-available solar panels are made with only one side exposed to sunlight.

### SUMMARY OF THE DISCLOSURE

Broadly, the present disclosure relates to improved photovoltaic solar cell systems and methods.

In one approach, a system includes a bifacial solar cell panel and at least one reflector. The panel may include a transparent top substrate, a plurality of semiconductor cells, and a plurality of top transparent conductive layers located between the transparent top substrate and the plurality of semiconductors cells. Each of the plurality of semiconductor cells may include a scribe line portion, with the scribe line portions of each semiconductor cell being generally parallel to one another. At least some of the top transparent conductive layers are separated from one another by the scribe line portions of the plurality of semiconductor cells. The panel may include a transparent bottom substrate and a plurality of bottom transparent conductive layers located proximal the plurality of semiconductor cells and the bottom transparent substrate. The panel may include a plurality of communication portions, wherein each communication portion is in communication with at least one of the plurality of top transparent conductive layers and a corresponding at least one of the plurality of bottom transparent conductive layers. The panel may further include a plurality of separators, wherein at least some of the plurality of bottom transparent conductive layers are separated from one another by the separators. The scribe line portions, separators and/or communication portions are arranged such that the semiconductor cells are connected in series. In one embodiment, the scribe line portions, separators and/or communication portions are arranged such that each of the semiconductor cells has a long axis.

The reflector is located proximal the panel. The reflector includes a lower portion having a long axis. The lower portion may face the panel. The long axis of the lower portion may be oriented such that it is transverse to at least one of (a) the long axis of the semiconductor cells, (b) the scribe line portions, (c) the separators and/or the (d) communication portions of the panel, thereby arranging the reflector and panel such that the long axis of the reflector is coincidental to (e.g., parallel to) the current flow direction of the panel. Having the current flow direction being parallel to the long axis of the reflector may enable each one of the semiconductor cells to receive approximately the same amount of photon incidence on the backside of the panel, if averaged over each cell of the semiconductor cells in series. Indeed, even though the photon flux on the backside of the panel may be non-uniform within any one cell (e.g., from the left side of the panel to the center of the panel), the average total photon-flux incident on across the semiconductor cells may be similar, or nearly identical. Thus, interconnecting the semiconductor cells in series and with their long axis transverse to the long axis of the reflector, and/or with the current flow being parallel to the long axis of the reflector, may improve panel efficiency without requiring an increase in panel surface area.

Associated methods of producing solar cell panels and generating electricity are also disclosed. In one aspect, a method includes producing a bifacial solar cell panel having a plurality of semiconductor cells electrically connected in series, where at least some of the semiconductor cells have a long axis. The method may further include orienting a reflector proximal the bifacial solar cell panel, wherein, as oriented, a long axis of the reflector is transverse to the long axis of at least some of the semiconductor cells. The method may include reflecting light towards the bifacial solar cell panel via the reflector, and, in response to the reflecting step, generating current by the bifacial solar cell panel. In one approach, the orienting step may include orienting the solar cell panel such that the long axis of the reflector is perpendicular to the long axis of at least some of the semiconductor cells. In one approach, the orienting step comprises orienting the solar cell panel such that the long axis of the reflector is parallel to the flow of electrical current through the semiconductor cells connected in series.

These and other aspects and advantages, and novel features of this new technology are set forth in part in the description that follows and will become apparent to those skilled in the art upon examination of the following description and figures, or may be learned by practicing one or more embodiments of the technology provided for by the present disclosure.

### BRIEF DESCRIPTION OF THE DRAWINGS

FIG. 1 is a partial, cross-sectional, schematic view of one embodiment of a photovoltaic system.

FIG. 2 is a cross-sectional schematic view of the photovoltaic system of FIG. 1 taken along line 2-2.

FIG. 3 is a perspective view of the photovoltaic system of FIG. 1, illustrating the semiconductor cells of the solar cell panel being connected in series.

FIG. 4 is a top view of the solar cell panel of FIG. 1.

FIGS. 5a-5i illustrate one embodiment of a method for producing the solar cell panel of FIG. 1.

FIG. 6 is a partial, cross-sectional, schematic view of another embodiment of a solar cell panel having photoresist scribe line portions.

FIG. 7 is a partial, cross-sectional, schematic view of another embodiment of a solar cell panel having metal conductor lines.

FIG. 8 is a perspective view of another embodiment of a photovoltaic system having several modules, each module comprising semiconductor cells connected in series.

FIG. 9 is a perspective view of another embodiment of a photovoltaic system having a dedicated module for junction box mounting.

FIG. 10 is one embodiment of a method for producing a solar cell assembly.

### DETAILED DESCRIPTION

Reference will now be made in detail to the accompanying drawings, which at least assist in illustrating various pertinent features of the new technology provided for by the present disclosure.

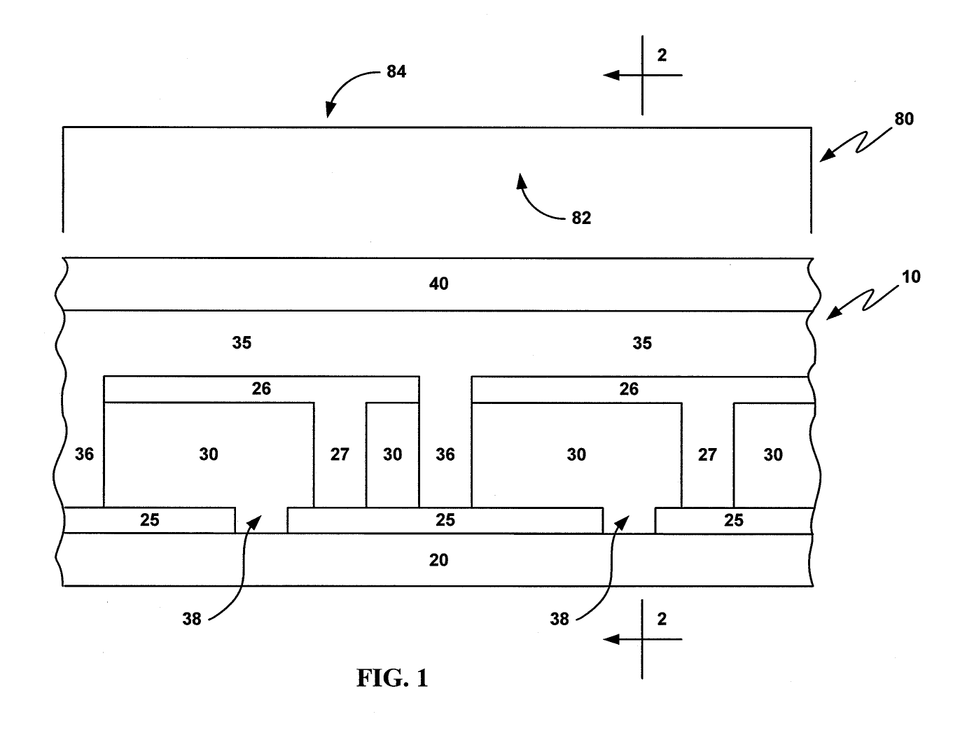

Referring now to FIGS. 1-4, one embodiment of a bifacial solar cell system is illustrated. In the illustrated embodiment, the system includes a solar cell panel 10 and a reflector 80 located proximal the panel 10 (shown upside-down in FIG. 1, for purposes of simplicity). The reflector 80 includes a lower portion 82 facing the panel 10. The lower portion 82 includes a long axis 84. The reflector 80 is configured to promote reflection of solar radiation (light) towards the panel 10.

The solar cell panel 10 includes a top transparent substrate 20 and a plurality of top transparent conductive layers 25 associated with (e.g., proximal to and/or located on) the top transparent substrate 20. The solar cell panel 10 includes a transparent bottom substrate 40 and a plurality of bottom transparent conductive layers 26 associated with (e.g., proximal to and/or located on) the bottom substrate 40. The panel 10 may optionally include an adhesive portion 35 associated with the plurality of bottom transparent conductive layers 26 and/or bottom transparent substrate 40.

The panel 10 further includes a plurality of semiconductor cells 30 between the plurality of bottom transparent conductive layers 26 and the plurality of top transparent conductive layers 25. The plurality of semiconductor cells 30 are electrically connected to one another in series, as defined by a plurality of separators 36 and a plurality communication portions 27. In the illustrated embodiment, each of the bottom transparent conductive layers 26 is in communication with at least one of the communication portions 27. At least some of these communication portions 27 are in communication with a corresponding one of the plurality of top transparent conductive layers 25. Each of the plurality of semiconductor cells also includes a scribe line portion 38, separating at least some of the top transparent conductive layers 26 from one another. The semiconductor cells 30 are configured such that each cell has a useful voltage, generally on the order of from about 0.5V to about 1.5V.

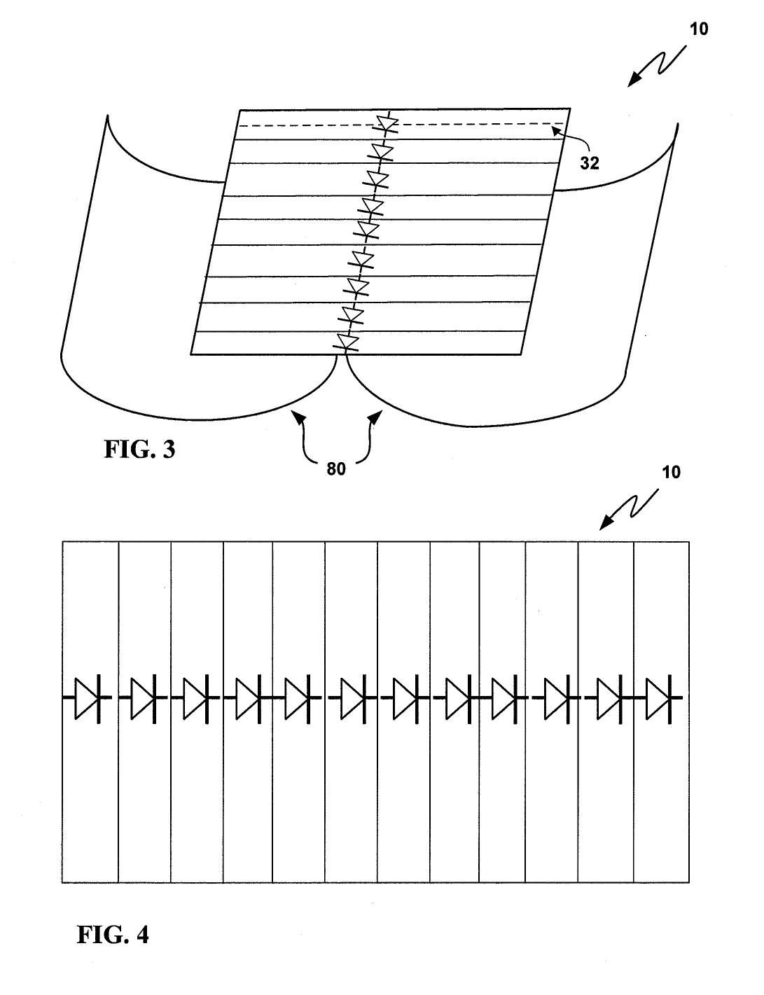

As described below, each of the scribe line portions 38, separators 36 and communication portions 27 are created via scribing (e.g., laser or mechanical) to divide each of the plurality of semiconductor cells 30 such that its long axis 32 (FIG. 3) is transverse to the long axis 84 of the reflectors 80 and/or such that the current flow is generally parallel to the long axis 84 of the reflector 80. In this regard, generally at least some of the scribe line portions 38, and preferably all of the scribe line portions 38 are parallel to one another. Furthermore, at least some of the scribe line portions 38, and preferably all of the scribe line portions 38, are transverse to the long axis 84 of the reflector 80. Likewise, generally at least some of the separators 36, and preferably all of the separators 36, are parallel to one another. Furthermore, at least some of the separators 36, and preferably all of the separators 36, are transverse to the long axis 84 of the reflector 80. Likewise, at least some of the communication portions 27, and preferably all of the communication portions 27, are parallel to one another. Furthermore, at least some of the communication portions 27, and preferably all of the communication portions 27, are transverse to the long axis 84 of the reflector 80.

As used herein, “transverse” means non-parallel. For example, a first line may be transverse to the long axis of the reflector(s). In one embodiment, a first line may be about perpendicular to the long axis of the reflector(s) (e.g., forming an angle of from about 86° to about 90°). In other embodiments, a first line may be non-perpendicular and non-parallel to the long axis of the reflector(s) (e.g., forming an angle of from about 45° to about 85°).

The illustrated bifacial solar cell system can absorb light from both sides (i.e., is bifacial), and over a larger area than the panel area itself. This is facilitated through the use of the reflectors 80 that promote light toward the backside (bottom substrate 40) of the solar cell panel 10. Furthermore, in the illustrated arrangement, the plurality of semiconductor cells 30 may be connected to one another in series, and with the long axis 32 of each of the semiconductor cells 30 being transverse to the long axis 84 of reflector 80. Thus, the semiconductor cells 30 are oriented such that the total light illuminating each cell is roughly equal for all semiconductor cells 30 even though any individual semiconductor cell may realize non-uniformities. However, since each cell of the semiconductor cells 30 may span the width of the panel 10, such non-uniformities within any one cell of the semiconductor cells 30 will be in parallel. Furthermore, having the long axis of the semiconductor cells 30 being transverse to the long axis 84 of reflector 80 allows each one of the semiconductor cells 30 to receive approximately the same amount of photon incidence on the backside of the panel 10, if averaged over each cell of the semiconductor cells 30 in series. Indeed, even though the photon flux on the backside of the panel 10 may be highly non-uniform within any one cell (e.g., from the left side of the panel to the center of the panel 10), the average total photon-flux incident on across the semiconductor cells 30 may be similar, or nearly identical. Thus, interconnecting the semiconductor cells 30 in series and with their long axis transverse to the long axis of the reflector and/or with the current flow being generally parallel to the long axis 84 of the reflector 80 may significantly improve panel efficiency without requiring an increase in panel surface area.

### The Top and Bottom Substrates

The top transparent substrate 20 and bottom transparent substrate 40 may be any suitable transparent materials adapted to contain a semiconductor stack and form the panel 10. Generally, the bottom transparent substrate 40 and top transparent substrate 20 are made from low iron glass, or other suitable transparent materials. As may be appreciated, since the solar cell panel 10 is bifacial, the use of terms such as “top”, “bottom”, “front”, “back” and the like, should not be construed as requiring any particular orientation, unless the context indicates otherwise. One or both of the top transparent substrate 20 and bottom transparent substrate 40 may be textured to decrease reflection and increase “light trapping”. Texturing may be completed via etching (e.g., wet etching) or embossing (e.g., hot embossing), among other techniques.

As shown in FIGS. 1-4, light generally enters the bottom (back) of the solar cell panel 10 via reflectors 80. In one embodiment, at least about 50% of the corresponding bottom surface of the semiconductor cells 30 is available for receiving light (i.e., is not shaded/covered by other materials). In other embodiments, at least about 70%, or at least about 90%, of the bottom surface of the semiconductor cells 30 is available for receiving light.

### The Semiconductor Cells

The semiconductor cells 30 generally comprise materials adapted for use in producing bifacial, thin film semiconductor solar cells. Some useful thin film, semiconductor materials include cadmium-telluride (CdTe), copper-indium-gallium-selenide (CIGS), silicon, and gallium arsenide (GaAs), among others. The skilled person will readily be able to select the appropriate semiconductor material based on the type of bifacial thin film solar panel being employed.

For CdTe and CIGS cells, the cells generally comprise a thin layer of CdS proximal the top transparent conductive oxide layers 25, followed by a layer of either CdTe or CIGS. The CdS layer typically has a thickness of from about 50 nm to about 300 nm. A CdTe layer generally has a thickness of from about 1.5 microns to about 5 microns. A CIGS layer generally has a thickness of from about 1.0 micron to about 2.5 microns. For CIGS cells, ZnS can be used in addition to or as a replacement for CdS.

For silicon cells, a thin film silicon stack may be employed and may include a single cell p-i-n structure (p-Si/i-Si/n-Si) or can also be a tandem cell or a triple junction cell (the various layers in the thin film silicon stack are not shown in the figure). The p-Si is typically boron doped silicon, the i-Si is undoped intrinsic silicon and the n-Si is typically phosphorous doped silicon.

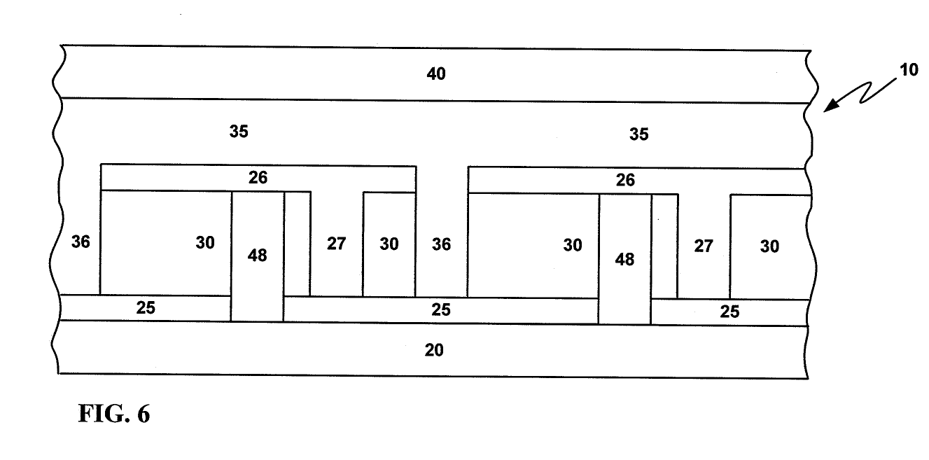

In the illustrated embodiment, the semiconductor cells 30 are connected in series, and include scribe line portions 38, which separate each of the plurality of top transparent conductive layers 25 from one another. However, as may be appreciated, many other configurations for connecting a plurality of semiconductor cells 30 in series exist. For example, and with reference now to FIG. 6, photoresist portions 48 (or a similar material) may be used in lieu of scribe line portions 38 to separate each of the plurality of top transparent conductive layers 25 from one another. The use of such photoresist portions 48 may increase performance by, for example, filing pinholes in the semiconductor cells 30.

### Top Transparent Conductive Layers

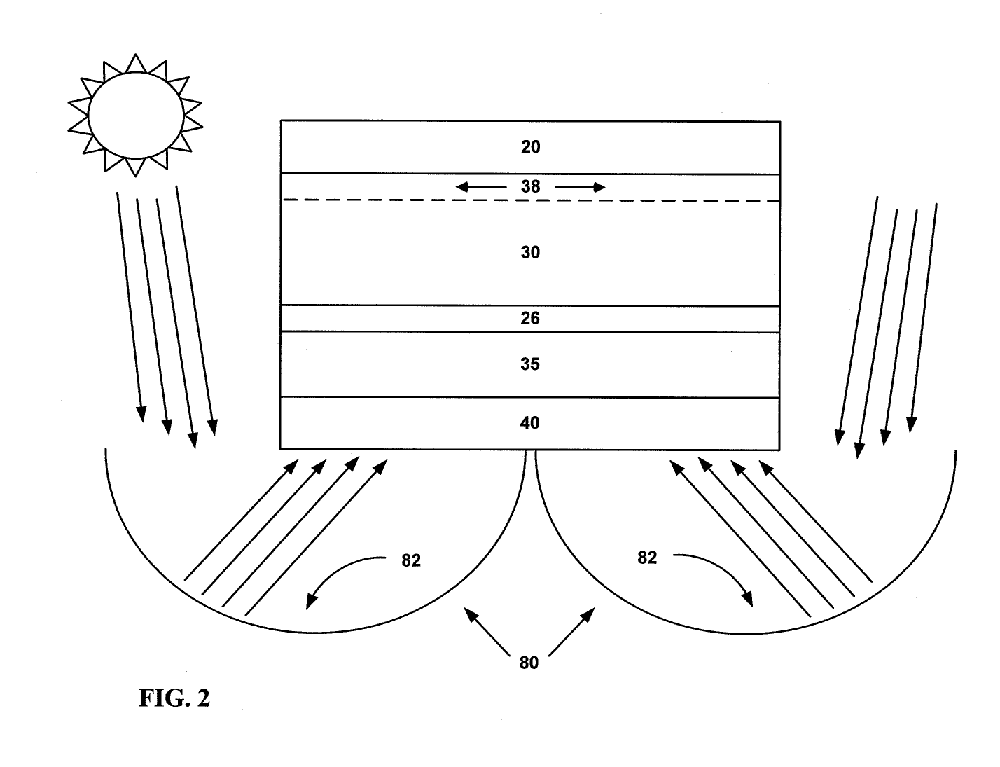

For CdTe and silicon-based semiconductors, the top transparent conductive oxide layer typically refers to layer 25 (due to superstrate processing methodology). For CIGS type semiconductors, the top transparent conductive oxide layer typically refers to layer 26 (due to a substrate processing methodology). Referring now to FIGS. 1-2, the plurality of top transparent conductive layers are generally made of conductive oxide materials.

For CdTe type semiconductor cells 30, the top transparent conductive layers 25 typically comprise two layers. The first layer is typically fluorinated tin oxide (SnO2:F), and is generally located proximal the top transparent substrate 20. The second layer may be one or more of intrinsic tin oxide (i-SnO2), undoped tin oxide (SnO2), or iridium oxide (IrO2). The second layer may be located proximal the CdS layer of the CdTe semiconductor cells. Iridium oxide has a work function that is similar to the work function of CdS and thus may be useful with thinner CdS layers (e.g., <100 nanometers). Intrinsic or undoped tin oxide may be useful with thicker CdS layers (e.g., about 300 nm).

For CIGS type semiconductor cells, the layers are generally reversed, where the bottom transparent conductive oxide layer is layer 25 and the top transparent conductive oxide layer is layer 26. In this embodiment, the top transparent conductive oxide layer 26 is typically comprises two layers. The first layer is typically aluminum-doped zinc oxide (ZnO:Al), and is generally located proximal the bottom transparent substrate 40. The second layer may be one or more of intrinsic zinc oxide (i-ZnO2) or undoped zinc oxide (ZnO2), and may be located proximal the CdS or ZnS layer of the CIGS semiconductor cells.

For silicon type semiconductor cells, the top transparent conductive layers 25 may be SnO2 and ZnO. ZnO materials may be Al doped, sputtered ZnO, or boron doped LPCVD ZnO.

The top transparent conductive layers may be textured to increase reflection and “light trapping”. The top transparent conductive layer may be textured by tailoring the CVD process used to deposit the transparent conductive layer(s), or by wet etching, among other techniques.

### Bottom Transparent Conductive Layers

For CdTe and silicon-based semiconductors, the bottom transparent conductive oxide layer typically refers to layer 26. For CIGS type semiconductors, the bottom transparent conductive oxide layer typically refers to layer 25. The plurality of bottom transparent conductive layers are generally conductive oxides. In some embodiments, the bottom transparent conductive layers are made of the same, or similar materials, to the top transparent conductive oxides. In other embodiments, the bottom transparent conductive layers comprise one or more of the below materials:

In one embodiment, a bottom transparent conductive layer includes an electron blocking layer located proximal the semiconductor cells 30. The electron blocking layer may employ one or more of WO (tungsten oxide), ZnTe (Zinc Telluride), doped silicon (e.g., p-doped silicon) and NiO (nickel oxide). When made of WO, ZnTe or NiO, this layer should have a thickness of not greater than about 10 nanometers, such as a thickness of not greater than about 6 nanometers, or not greater than about 3 nanometers. When made of doped silicon, this layer should have a thickness of not greater than about 15 nanometers, such as a thickness of not greater than about 5 nanometers, and is generally in the form of a-Si or microcrystalline silicon, and may be carbon doped.

In one embodiment, a bottom transparent conductive layer includes a work function contact layer located proximal the electron blocking layer. The work function contact layer may employ WN (tungsten nitride), MoN (molybdenum nitride), MO (molybdenum oxide) and V₂O₅ (vanadium oxide). This layer should have a thickness of not greater than about 3 nanometers, such as not greater than about 1 nanometer, or not greater than about 0.5 nanometer, or not greater than about 0.2 nanometer. In some embodiments, the bottom transparent conductive layers 26 are molybdenum-free and/or tungsten-free.

In one embodiment, a bottom transparent conductive layer includes a work function oxide layer located proximal the work function contact layer. The work function oxide layer may employ one or more of metal oxides, such as gallium indium oxide (GIO) or ZnSnO₃ (zinc stannate), and generally have a thickness in the range of from about 30 nanometers to about 50 nanometers.

In one embodiment, a bottom transparent conductive layer includes a bulk transparent conductive oxide layer. The bulk oxide layer may employ one or more transparent metal oxides, such as oxides of zinc, indium, and tin, which may be doped with one or more of aluminum, boron, fluorine, and gallium, among others, and generally have a thickness in the range of from about 200 nanometers to about 1000 nanometers (1 micron).

Thus, in some embodiments, the plurality of bottom transparent conductive layers comprise at least one of:

(a) an oxide of tin, zinc, gallium, indium, tungsten, vanadium, molybdenum; and

(b) a nitride of tungsten or molybdenum;

(c) silicon; and

(d) combinations thereof.

In one embodiment, the bottom transparent conductive layers comprise at least one of tin oxide and zinc oxide, optionally fluorinated and/or aluminum doped, optionally with one of the following materials:

(a) gallium indium oxide and/or zinc stannate;

(b) tungsten nitride, molybdenum nitride, molybdenum oxide, and/or vanadium oxide;

(c) silicon, optionally p-doped or carbon-doped;

(d) tungsten oxide and/or zinc telluride; and

(e) combinations thereof.

The bottom transparent conductive layers may be textured to increase reflection and “light trapping”. The bottom transparent conductive layer may be textured by tailoring the CVD process used to deposit the transparent conductive layer(s), or by wet etching, among other techniques.

### Communication Portions

The communication portions 27 generally comprises the same material as the bottom transparent conductive layers 26, and therefore may be integral with the bottom transparent conductive layers 26. However, in other embodiments the connector materials may be made of different materials, such as any of the transparent conductive oxide materials described above.

### Separators

The separators 36 may be any material that facilitates electrical isolation of the semiconductor cells 30. In the illustrated embodiment, the separators are generally absent of solids and liquids, and thus in the form of a gas (e.g., air). Other electrically insulating materials may be employed as the separators 36. In one embodiment, at least some of the separators 36 comprise the same material as the adhesive portion 35 (when employed), and thus may be integral with the adhesive portion 35. In these embodiments, one portion of a separator 36 may include an adhesive material and another portion of a separator 36 may comprise a gas (e.g., air).

### Adhesive

The adhesive portion 35 may be any suitable transparent adhesive material. Examples of suitable transparent adhesives include ethyl-vinyl-acetate (EVA) and poly-vinyl-butyral (PVB). Other materials may be employed.

### Reflector

The reflectors 80 may be any suitable device adapted to reflect solar radiation toward the bottom transparent substrate 40 of the solar cell panel 10. In the illustrated embodiment of FIGS. 1-4, the system employs two reflectors 80 interconnected to the bottom of the panel 10. However, any number of reflectors 80 may be used with a panel. 10 and on any side of the panel 10. As shown in FIG. 2, the arrangement/orientation of the reflectors 80 and the panel 10 should allow for light to reflect towards the panel 10. Generally, this arrangement is promoted via the use of suitable frames adapted to hold the panel 10 and/or reflectors 80 proximal to one another and at a suitable distance from one another.

The reflectors 80 should have a lower portion 82 that includes a long axis 84. This long axis 84 should be arranged/oriented to be transverse to the long axis 32 of the semiconductor cells 30, for the reasons describe above. In this regard, the long axis 84 of the reflector 80 may, in some instances, symmetrically divide the reflector 80.

Particularly preferred reflectors 80 include objects having a rounded/curved outer surface configured to direct solar radiation toward the bottom transparent substrate 40 of the solar cell panel 10. In one embodiment, the reflector is a half-cylinder shaped, as illustrated in FIGS. 1-4. In these embodiments, the reflector has a generally curved shape in two dimensions and extends linearly in the third dimension. As used herein, “half-cylindrical shaped reflector” means any type of curved reflector that is adapted to promote reflection of solar radiation towards the solar cell panel. Other curved objects having a long axis may be employed.

Non-curved reflectors 80 may be used in some circumstances. Examples of such non-curved reflectors include geometric solids, such as a triangular solid, a pentagonal solid, and a hexagonal solid, among others. These non-curved reflectors have a linear outer surface.

### Method of Making the Solar Cell Panel and System

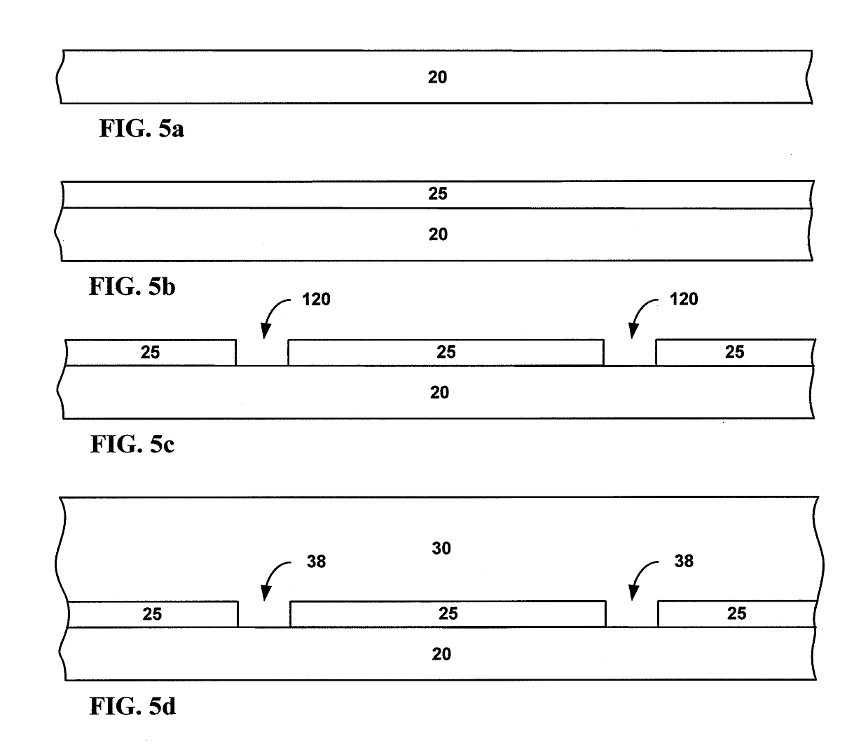

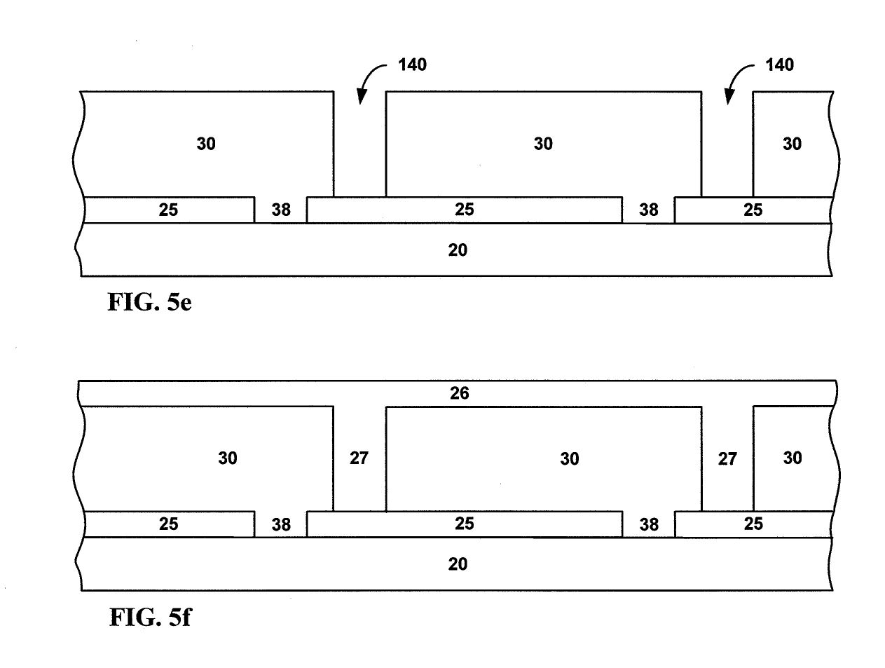

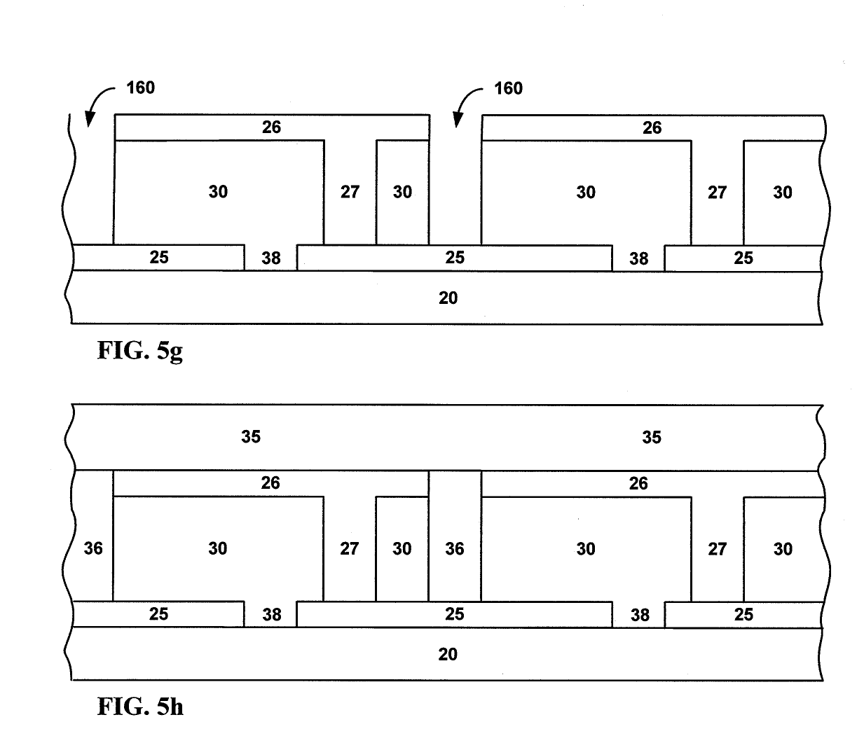

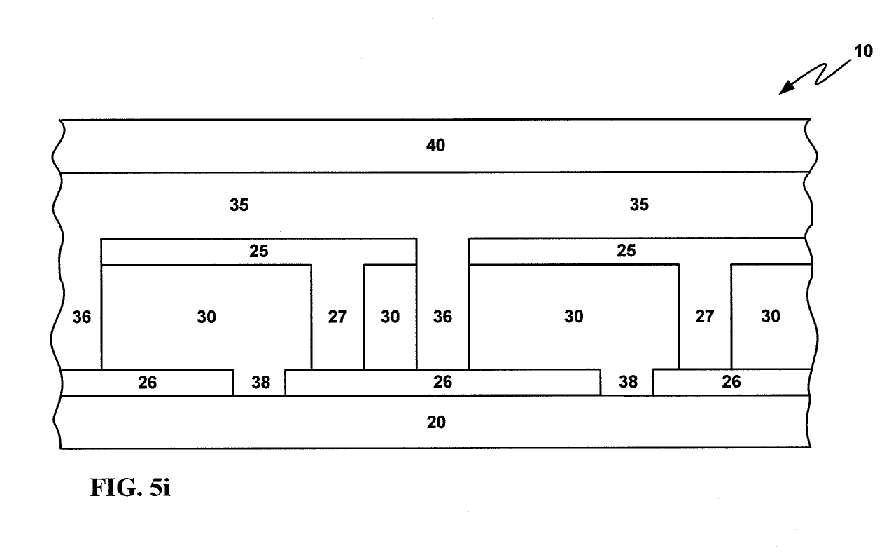

The solar cell panel 10 may be produced via substrate and superstrate manufacturing processes. A substrate manufacturing process uses a bottom substrate 40 to facilitate production of the panel 10. A superstrate manufacturing process uses a top transparent substrate 20 to facilitate manufacturing of the panel 10. One embodiment of a superstrate manufacturing process is illustrated in FIGS. 5a-5i. The process begins with a top transparent substrate 20 being prepared in a suitable fashion (FIG. 5a), after which a top transparent conductive layer 25 is deposited (FIG. 5b). Next, the single transparent conductive layer 25 may be separated into a plurality of transparent conductive layers 25 via laser scribing (or mechanically scribing), which creates scribe line portions 120 (FIG. 5c). Next, semiconductor 30 may be deposited thereby creating semiconductor layer 30 and scribe line portions 38 (FIG. 5d). Next, the single semiconductor layer 30 may be separated into a plurality of semiconductor cells via scribing, which create scribe line portions 140 (FIG. 5e). Next, the bottom transparent conductive layer 26 may be deposited, which may concomitantly produce communication portions 27 (FIG. 50. Next, separator portions 36 may be created by scribing the bottom transparent conductive layer 26, thereby separating it into a plurality of bottom transparent conductive layers 26 and having scribe portion 160 (FIG. 5g). Next, a transparent adhesive 35 may be applied to the stack creating adhesive layer 35 (FIG. 5h). Finally, bottom transparent substrate 40 may be connected to the stack thereby creating panel 10 (FIG. 5i).

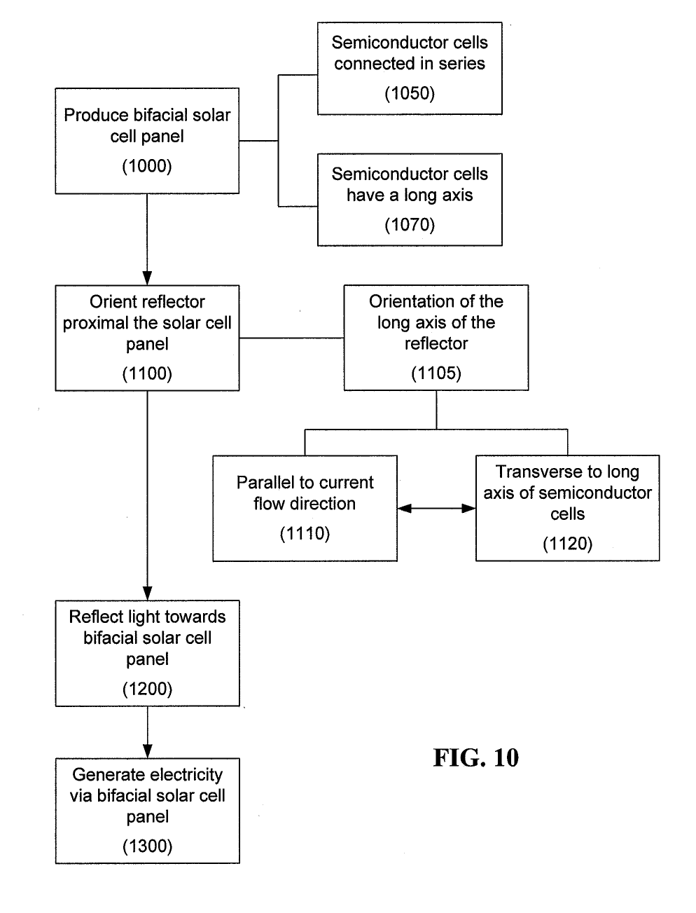

One embodiment of a methods for producing a solar cell systems and generating electricity is illustrated in FIG. 10. In the illustrated embodiment, the method includes producing a bifacial solar cell panel (1000) having a plurality of semiconductor cells electrically connected in series (1050), where at least some of the semiconductor cells have a long axis (1070). The illustrated method further includes the step of orienting a reflector proximal the solar cell panel (1100). The orientation may be accomplished such that the long axis of the reflector (1105) may be transverse to (e.g., perpendicular to) the long axis of at least some of the semiconductor cells (1120) and/or such that the long axis of the reflector is parallel to the flow of electrical current through the semiconductor cells connected in series (1110). The illustrated method further includes the step of include reflecting light towards the bifacial solar cell panel via the reflector (1200), and, in response to the reflecting step, generating current by the bifacial solar cell panel (1300).

### Additional Embodiments

Metal Conductivity Lines

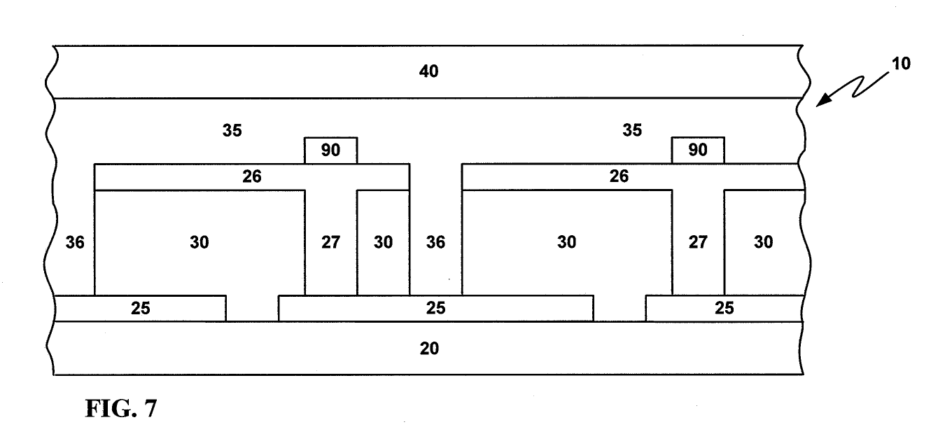

In some embodiments, metal lines may be added to the solar cell panel to facilitate current travel over the panel. For example, and with reference now to FIG. 7, a plurality of metal lines 90 are employed in conjunction with the bottom transparent conductive layers 26. These metal lines 90 may increase conductivity in the panel 10, which may facilitate travel of current over longer distances. These metal lines 90 may be used to increase current transport between portions of a cell having low photon yield and portions of a cell having high photon yield. The size of the metal lines 90 should be restricted so as to restrict shading of the cell. In one embodiment, the metal line are disposed coincidental to the separator 36 (e.g., directly above as shown in FIG. 7) and/or communication portion 27, which may restrict/eliminate shading issues. In one embodiment, at least some of the semiconductor cells (and in some cases all of the cells) include a corresponding metal line 90. The metal lines may be deposited using any known methods, including additive and subtractive methods. The metal lines may be any suitable high conductivity material, such as copper or aluminum.

Multiple Cell Modules

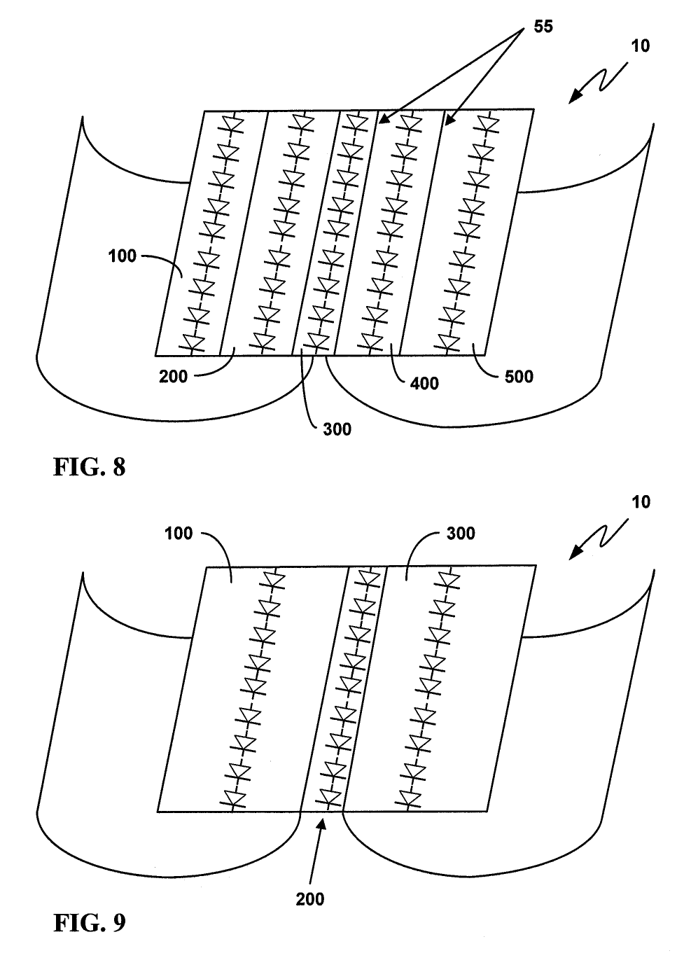

In the illustrated embodiment of FIGS. 1-4, the panel 10 included a single solar cell module of semiconductor cells 30 in series. However, in some embodiments, a panel may include multiple solar cell modules of semiconductor cells 30 connected in series. For example, and with reference now to FIG. 8, a panel 10 may include a plurality of solar cell modules 100-500. Each of the solar cell modules 100-500 includes its own plurality of semiconductor cells 30 connected in series. This arrangement may facilitate increased panel efficiency, such as by reducing the averaging requirement over each of the cells.

The separate solar cell modules of the panel 10 may be create by using isolation lines 55 (e.g., created via scribing) that may cut through the entire cell, with the modules 100-500 being connected in parallel at the end of the panel 10. In another embodiment, the isolation lines 55 may cut through the absorber layer only.

In one embodiment, and with reference now to FIG. 9, a panel may include a plurality of different modules 100, 200, 300. The backside of a center module 200 may be utilized for junction box mounting, and thus may have a reduced/restricted size compared to the other modules 100, 300. The use of a junction box (not illustrated) may hinder light reception in the area of the backside of the center module 200. The use of the electrically isolated module 200 may reduce the effect of the junction box on solar efficiency of the panel 10.

In other words, in one embodiment, the panel 10 include a plurality of solar cell modules, and a first module is electrically isolated from a second module via at least one isolation line 55. Despite the electrical isolation, both the first and second modules contain the same materials, e.g., the semiconductor cells 30, the plurality of top transparent conductive layers 25, and the plurality of bottom transparent conductive layers 26 located proximal the plurality of semiconductor cells 30. By separating the panel 10 into modules, the panel efficiency may increase, such as by reducing the averaging requirement over each of the cells. In one embodiment, a second module is associated with a junction box.

While various embodiments of the new technology described herein have been described in detail, it is apparent that modifications and adaptations of those embodiments will occur to those skilled in the art. However, it is to be expressly understood that such modifications and adaptations are within the spirit and scope of the presently disclosed technology.

What is claimed is:

1. A photovoltaic system comprising:
(i) a solar cell panel comprising:
(a) a transparent top substrate;
(b) a plurality of semiconductor cells;
wherein each of the plurality of semiconductor cells includes a scribe line portion;
wherein the scribe line portions run parallel to one another;
(c) a plurality of top transparent conductive layers located between the transparent top substrate and the plurality of semiconductors cells;
wherein at least some of the top transparent conductive layers are separated from one another by the scribe line portions of the plurality of semiconductor cells;
(d) a plurality of bottom transparent conductive layers located on the plurality of semiconductor cells;
(e) a plurality of communication portions, wherein each communication portion is in communication with at least one of the plurality of top transparent conductive layers and a corresponding at least one of the plurality of bottom transparent conductive layers, thereby electrically connecting the plurality of semiconductor cells to one another in a series;
(f) a plurality of separators, wherein at least some of the plurality of bottom transparent conductive layers are separated from one another by the separators; and
(g) a bottom top substrate located above the plurality of top transparent conductive layers; and
(ii) at least one reflector located proximal the panel,
wherein the reflector includes a lower portion having a long axis, wherein the lower portion faces the panel, and wherein the long axis of the lower portion is transverse to the plurality of scribe line portions of the semiconductor cells of the panel.

2. The system of claim 1, wherein one of the bottom transparent conductive layers and top transparent conductive oxide layers comprise at least one of:
tin oxide and zinc oxide, optionally fluorinated and/or aluminum doped; and
optionally one of the following materials:
(1) gallium indium oxide and/or zinc stannate;
(2) tungsten nitride, molybdenum nitride, molybdenum oxide and/or vanadium oxide;
(3) silicon, optionally p-doped or carbon-doped;
(4) tungsten oxide, zinc telluride and/or nickel oxide; and
(5) combinations thereof.

3. The system of claim 1, wherein the at least one reflector comprises a rounded outer surface.

4. The system of claim 3, wherein the at least one reflector is in the form of half-cylindrical shape.

5. The system of claim 1, further comprising:
at least one metal conductor line disposed proximal at least one of the plurality of semiconductor cells.

6. The system of claim 5, wherein the at least one metal conductor line is about parallel to the plurality of scribe line portions of the plurality of semiconductor cells.

7. The system of claim 6, wherein the at least one metal conductor line is disposed coincidental to at least one of (a) at least one of the separators; (b) at least one of the communication portions; and (c) combinations thereof.

8. The system of claim 7, wherein the at least one metal conductor line is disposed directly above at least one of the separators.

9. The system of claim 7, wherein the at least one metal conductor line is disposed directly above at least one of the communication portions.

10. The system of claim 1, wherein the panel include a plurality of solar cell modules, wherein a first module is electrically isolated from a second module via at least one isolation line, wherein both the first and second modules contain the semiconductor cells, the plurality of top transparent conductive layers, and the plurality of bottom transparent conductive layers located on the plurality of semiconductor cells.

11. The system of claim 9, wherein the second module is associated with a junction box.

12. A method comprising:
(a) producing a bifacial solar cell panel having a plurality of semiconductor cells electrically connected in series;
(i) wherein at least some of the semiconductor cells have a long axis;
(b) orienting a reflector proximal the bifacial solar cell panel, wherein, as oriented, a long axis of the reflector is transverse to the long axis of at least some of the semiconductor cells;
(c) reflecting light towards the bifacial solar cell panel via the reflector; and
(d) generating current via the bifacial solar cell panel in response to the reflecting step (c).

13. The method of claim 12, wherein the orienting step comprises orienting the solar cell panel such that the long axis of the reflector is perpendicular to the long axis of at least some of the semiconductor cells.

14. The method of claim 12, wherein the wherein the orienting step comprises orienting the solar cell panel such that the long axis of the reflector is parallel to the flow of electrical current through the semiconductor cells connected in series.
